(19) United States
(12) Patent Application Publication
(10) Pub. No.: US 2024/0178637 A1
(43) Pub. Date: May 30, 2024

(54) LIGHT-EMITTING DEVICE, THREE-DIMENSIONAL SHAPING APPARATUS, AND HEAD-MOUNTED DISPLAY

(71) Applicant: SEIKO EPSON CORPORATION, Tokyo (JP)

(72) Inventor: Masamitsu MOCHIZUKI, CHINO-SHI (JP)

(73) Assignee: SEIKO EPSON CORPORATION, Tokyo (JP)

(21) Appl. No.: 18/519,070

(22) Filed: Nov. 27, 2023

(30) Foreign Application Priority Data
Nov. 30, 2022 (JP) 2022-191198

(51) Int. Cl. H01S 5/343; H01S 5/183

(52) U.S. Cl. CPC H01S 5/34333; H01S 5/18361

(57) ABSTRACT

A light-emitting device includes a first multi layer film mirror composed of a plurality of first semiconductor layers having first conductivity type, a second multi layer film mirror, a light-emitting layer provided between the first multi layer film mirror and the second multi layer film mirror, a GaN-based semiconductor layer having second conductivity type different from the first conductivity type, the GaN-based semiconductor layer being provided between the light-emitting layer and the second multi layer film mirror, a second semiconductor layer having the second conductivity type, the second semiconductor layer including a first portion provided between the GaN-based semiconductor layer and the second multi layer film mirror, and a second portion not overlapping the second multi layer film mirror as viewed in a lamination direction of the first multi layer film mirror and the light-emitting layer, and an electrode provided at the second portion. A band gap of a material of the second semiconductor layer is greater than a band gap of a material of the light-emitting layer, and smaller than a band gap of a material of the GaN-based semiconductor layer.

The present application is based on, and claims priority from JP Application Serial Number 2022-191198, filed Nov. 30, 2022, the disclosure of which is hereby incorporated by reference herein in its entirety.

### BACKGROUND

### 1. Technical Field

The present disclosure relates to a light-emitting device, a three-dimensional shaping apparatus, and a head-mounted display.

### 2. Related Art

Vertical cavity surface emitting lasers (VCSELs) that emit light in the direction perpendicular to the substrate surface are known.

For example, JP-A-2004-72118 discloses a VCSEL including a lower DBR layer, an upper DBR, an active layer provided between the lower DBR layer and the upper DBR, a p-type semiconductor layer provided between the active layer and the upper DBR layer, and an electrode provided at the p-type semiconductor layer. In JP-A-2004-72118, the upper DBR is provided at the center of p-type semiconductor layer, and the electrode is provided at an end portion of the p-type semiconductor layer.

In the above-described VCSEL, GaN-based semiconductor materials are used for emitting blue and green laser light. However, p-type semiconductor layers composed of GaN-based semiconductor materials have high resistivity, and as such the current injected from the electrode is less injected into the center of the active layer.

### SUMMARY

A light-emitting device according to one aspect of the present disclosure includes a first multi layer film mirror composed of a plurality of first semiconductor layers having first conductivity type, a second multi layer film mirror, a light-emitting layer provided between the first multi layer film mirror and the second multi layer film mirror, a GaN-based semiconductor layer having second conductivity type different from the first conductivity type, the GaN-based semiconductor layer being provided between the light-emitting layer and the second multi layer film mirror, a second semiconductor layer having the second conductivity type, the second semiconductor layer including a first portion provided between the GaN-based semiconductor layer and the second multi layer film mirror, and a second portion not overlapping the second multi layer film mirror as viewed in a lamination direction of the first multi layer film mirror and the light-emitting layer, and an electrode provided at the second portion. A band gap of a material of the semiconductor layer of the second conductivity type is greater than a band gap of a material of the light-emitting layer, and smaller than a band gap of a material of the GaN-based semiconductor layer.

A three-dimensional shaping apparatus according to one aspect of the present disclosure includes the above-described light-emitting device according to the aspect.

A head-mounted display according to one aspect of the present disclosure includes the above-described light-emitting device according to the aspect.

### BRIEF DESCRIPTION OF THE DRAWINGS

FIG. 1 is a sectional view schematically illustrating a light-emitting device according to an embodiment.

FIG. 2 is a sectional view schematically illustrating a manufacturing process of the light-emitting device according to the embodiment.

FIG. 3 is a sectional view schematically illustrating a light-emitting device according to a first modification of the embodiment.

FIG. 4 is a sectional view schematically illustrating a light-emitting device according to a second modification of the embodiment.

FIG. 5 is a diagram schematically illustrating a three-dimensional shaping apparatus according to the embodiment.

FIG. 6 is a diagram schematically illustrating a light source of the three-dimensional shaping apparatus according to the embodiment.

FIG. 7 is a diagram schematically illustrating a three-dimensional shaping apparatus according to a modification of the embodiment.

FIG. 8 is a perspective view schematically illustrating a head-mounted display according to the embodiment.

FIG. 9 is a diagram for describing an optical system of the head-mounted display according to the embodiment.

### DESCRIPTION OF EMBODIMENTS

Preferred embodiments of the present disclosure are described in detail below with reference to the drawings. Note that is the following description does not unduly limit the contents of the present disclosure. In addition, not all of the configurations described below are essential to the invention.

### 1. Light-Emitting Device

### 1.1. Configuration

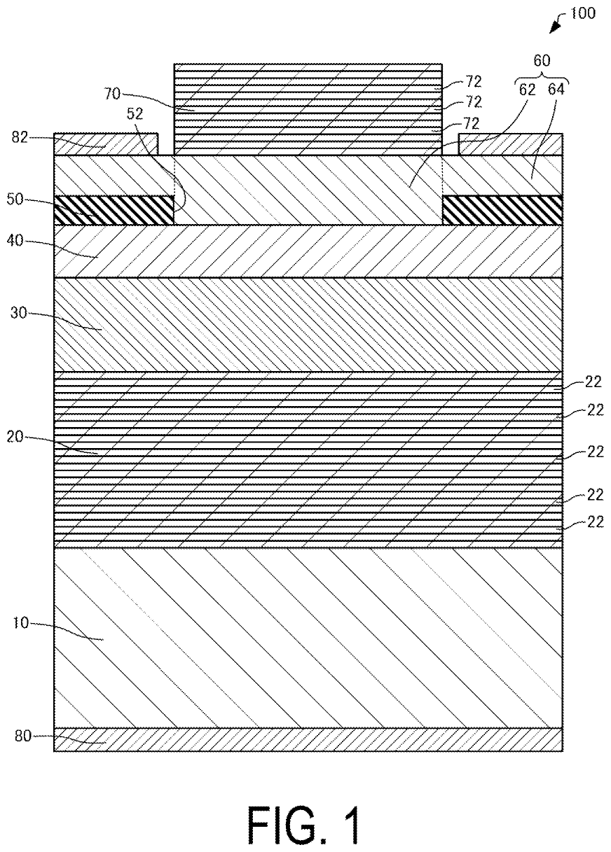

First, a light-emitting device according to an embodiment is described with reference to the drawings. FIG. 1 is a sectional view schematically illustrating a light-emitting device 100 according to the embodiment.

As illustrated in FIG. 1, the light-emitting device 100 includes a substrate 10, a first multi layer film mirror 20, a light-emitting layer 30, a GaN-based semiconductor layer 40, an insulating layer 50, a semiconductor layer 60, a second multi layer film mirror 70, a first electrode 80, and a second electrode 82, for example. The light-emitting device 100 is a VCSEL that emits blue light and green light, for example.

The substrate 10 is a first conductivity type, for example. The first conductivity type is the n-type, for example. The substrate 10 is an Si doped n-type GaN substrate, for example.

The first multi layer film mirror 20 is provided on the substrate 10. The first multi layer film mirror 20 is provided between the substrate 10 and the light-emitting layer 30. The first multi layer film mirror 20 is composed of a plurality of semiconductor layers 22. The plurality of semiconductor layers 22 is the n-type, for example. The plurality of semiconductor layers 22 is composed of a high refractive index layer and a low refractive index layer with a lower refractive index than the high refractive index layer. The first multi layer film mirror 20 is a DBR (Distributed Bragg Reflector) in which the high refractive index layer and the low refractive index layer are alternately stacked. The high refractive index layer is an Si doped n-type GaN layer, for example. The low refractive index layer is an Si doped n-type InAlN layer (such as In_{0.18}Al_{0.82}N layer), for example. The number of the plurality of semiconductor layers 22 is not limited.

Note that in this specification, the direction from the light-emitting layer 30 toward the second multi layer film mirror 70 is described as “upper direction” and the direction from the light-emitting layer 30 toward the first multi layer film mirror 20 is described as “lower direction” with respect to the light-emitting layer 30 as a reference in the lamination direction of the first multi layer film mirror 20 and the light-emitting layer 30 (hereinafter simply referred to also as “lamination direction”). In addition, the direction orthogonal to the lamination direction is referred to also as “plane direction”.

The light-emitting layer 30 is provided on the first multi layer film mirror 20. The light-emitting layer 30 is provided between the first multi layer film mirror 20 and the second multi layer film mirror 70. In the example illustrated in the drawing, the light-emitting layer 30 is provided between the first multi layer film mirror 20 and the GaN-based semiconductor layer 40. The light-emitting layer 30 generates light when current is injected into it. The light-emitting layer 30 includes a well layer and a barrier layer, for example. The well layer and the barrier layer are i-type semiconductor layers where impurities are undoped intentionally. The well layer is an InGaN layer, for example. The barrier layer is a GaN layer, for example. The light-emitting layer 30 has a MQW (Multiple Quantum Well) structure composed of the well layer and the barrier layer.

Note that the number of well layers and barrier layers making up the light-emitting layer 30 is not limited. For example, only one well layer may be provided, and in this case, the light-emitting layer 30 has a SQW (Single Quantum Well) structure.

The GaN-based semiconductor layer 40 is provided on the light-emitting layer 30. The GaN-based semiconductor layer 40 is provided between the light-emitting layer 30 and the second multi layer film mirror 70. In the example illustrated in the drawing, the GaN-based semiconductor layer 40 is provided between the light-emitting layer 30 and the semiconductor layer 60. The GaN-based semiconductor layer 40 is a second conductivity type different from the first conductivity type. The second conductivity type is the p-type, for example. The GaN-based semiconductor layer 40 is a semiconductor layer containing Ga and N. The GaN-based semiconductor layer 40 is an Mg doped p-type GaN layer. Note that the GaN-based semiconductor layer 40 may be an InGaN layer, or an AlGaN layer.

The insulating layer 50 is provided on the GaN-based semiconductor layer 40. The insulating layer 50 is provided between the GaN-based semiconductor layer 40 and the semiconductor layer 60. The insulating layer 50 is a silicon oxide layer (SiO₂ layer), for example. An opening 52 is formed in the insulating layer 50. As viewed in the lamination direction, the opening 52 overlaps the second multi layer film mirror 70. As viewed in the lamination direction, the insulating layer 50 does not overlap the second multi layer film mirror 70, for example. The current injected by the first electrode 80 and the second electrode 82 into the light-emitting layer 30 flows through the opening 52. The insulating layer 50 is a current narrowing layer.

The semiconductor layer 60 is provided on the GaN-based semiconductor layer 40 and the insulating layer 50. The semiconductor layer 60 includes a first portion 62 and a second portion 64.

The first portion 62 of the semiconductor layer 60 is provided between the GaN-based semiconductor layer 40 and the second multi layer film mirror 70. The opening 52 is filled with the first portion 62. The refractive index of the semiconductor layer 60 is higher than the refractive index of the insulating layer 50. Therefore, the light generated at the light-emitting layer 30 can be confined to the first portion 62 overlapping the second multi layer film mirror 70 as viewed in the lamination direction. In the example illustrated in the drawing, the thickness of the first portion 62 is greater than the thickness of the GaN-based semiconductor layer 40.

Note that in the case where the second multi layer film mirror 70 is larger than the opening 52 as viewed in the lamination direction, if the opening of the second electrode 82 is correspondingly large, it is difficult to inject current into the inside of the light-emitting layer (the resistance increases) in some situation. However, on the other hand, the second multi layer film mirror can function as a reflection film also for the light exuded to the insulating layer 50 while being confined to the first portion 62. That is, by the trade-off of the resistance and optical confinement, the second multi layer film mirror 70 slightly (by about 2 um or less) larger (smaller) than the insulating layer 50 and the like can be selected, for example.

The second portion 64 of the semiconductor layer 60 is continuous with the first portion 62. As viewed in the lamination direction, the second portion 64 is provided at a position not overlapping the second multi layer film mirror 70. The second portion 64 is provided between the insulating layer 50 and the second electrode 82. In the example illustrated in the drawing, the thickness of the second portion 64 is smaller than the thickness of the first portion 62.

The semiconductor layer 60 is the p-type. The semiconductor layer 60 is a SiC layer, for example. The semiconductor layer 60 has an impurity concentration of 1×10¹⁸ cm⁻³ or greater in a value activated at room temperature heat energy, for example. In the semiconductor layer 60, the impurity concentration can be higher than in the GaN-based semiconductor layer 40. The resistivity of the semiconductor layer 60 is lower than the resistivity of the GaN-based semiconductor layer 40. The band gap of the semiconductor layer 60 is greater than the band gap of the material of the light-emitting layer 30, and smaller than the band gap of the material of the GaN-based semiconductor layer 40. In addition, the difference between the band gap of the material of the light-emitting layer 30 and the band gap of the semiconductor layer 60 may be greater than the difference between the band gap of the semiconductor layer 60 and the band gap of the material of the GaN-based semiconductor layer 40.

The semiconductor layer 60 is composed of 4H-SiC, for example. Note that the semiconductor layer 60 may have a 4H-SiC content of 90 wt % or more, preferably 95 wt % or more, more preferably 99 wt % or more, with SiC of other crystal structures for the remaining content. Examples of the SiC of other crystal structures include 6H-SiC, and 3C-SiC. The crystal structure of the semiconductor layer 60 is specified by x-ray diffraction, for example.

The second multi layer film mirror 70 is provided on the first portion 62 of the semiconductor layer 60. The second multi layer film mirror 70 is composed of a plurality of dielectric layers 72, for example. The plurality of dielectric layers 72 is composed of a high refractive index layer and a low refractive index layer with a lower refractive index than the high refractive index layer. The second multi layer film mirror 70 is a DBR in which the high refractive index layer and the low refractive index layer are alternately stacked. The high refractive index layer is a Nb₂O₅ layer, for example. The low refractive index layer is a SiO₂ layer, for example. The number of the plurality of dielectric layers 72 is not limited.

The first electrode 80 is provided below the substrate 10. The substrate 10 is provided between the first electrode 80 and the first multi layer film mirror 20. The substrate 10 may be in ohmic contact with the first electrode 80. The first electrode 80 is electrically coupled to the first multi layer film mirror 20 through the substrate 10. As the first electrode 80, a laminate in which a Ti layer, an Au layer, a Pt layer and an Au layer are provided in this order from the substrate 10 side, or the like is used, for example. The first electrode 80 is one electrode for injecting current into the light-emitting layer 30.

The second electrode 82 is provided on the second portion 64 of the semiconductor layer 60. The second portion 64 may be in ohmic contact with the second electrode 82. In the example illustrated in the drawing, the second electrode 82 is separated from the second multi layer film mirror 70. As viewed in the lamination direction, the second electrode 82 surrounds the second multi layer film mirror 70, for example. The second electrode 82 is electrically coupled to the GaN-based semiconductor layer 40 through the semiconductor layer 60. As the second electrode 82, a laminate in which a Ti layer, an Al layer and an Au layer are provided in this order from the semiconductor layer 60 side, or the like is used, for example. The second electrode 82 is the other electrode for injecting current into the light-emitting layer 30.

### 1.2. Operation

In the light-emitting device 100, a pin diode is composed of the p-type GaN-based semiconductor layer 40, the i-type light-emitting layer 30, and the n-type first multi layer film mirror 20. In the light-emitting device 100, when a forward bias voltage of the pin diode is applied between the first electrode 80 and the second electrode 82, current is injected into the light-emitting layer 30 and recombination between electrons and holes occurs in the light-emitting layer 30. This recombination causes light emission. The light generated at the light-emitting layer 30 is reflected multiple times between the first multi layer film mirror 20 and the second multi layer film mirror 70 to form standing waves, and obtains a gain at the light-emitting layer 30 to generate laser oscillation. Then, the light-emitting device 100 emits a laser light in the lamination direction from the second multi layer film mirror 70 side.

### 1.3. Operation and Effect

The light-emitting device 100 includes the first multi layer film mirror 20 composed of the plurality of semiconductor layers 22 of the first conductivity type, the second multi layer film mirror 70, the light-emitting layer 30 provided between the first multi layer film mirror 20 and the second multi layer film mirror 70, and the GaN-based semiconductor layer 40 of the second conductivity type different from the first conductivity type provided between the light-emitting layer 30 and the second multi layer film mirror 70. Further, the light-emitting device 100 includes the first portion 62 provided between the GaN-based semiconductor layer 40 and the second multi layer film mirror 70, the second portion 64 not overlapping the second multi layer film mirror 70 as viewed in the lamination direction, the semiconductor layer 60 of the second conductivity type, and the second electrode 82 provided at the second portion 64. The band gap of semiconductor layer 60 of the second conductivity type is greater than the band gap of the material of the light-emitting layer 30, and smaller than the band gap of the material of the GaN-based semiconductor layer 40.

Therefore, in the light-emitting device 100, the current from the second electrode 82 flows in the plane direction in the semiconductor layer 60 and reaches the GaN-based semiconductor layer 40 so as to be injected into the light-emitting layer 30. The resistivity of the semiconductor layer 60 is lower than the resistivity of the GaN-based semiconductor layer 40. In this manner, the current is easily injected into the center portion of the light-emitting layer 30 in comparison with the case where the semiconductor layer as a SiC layer is not provided, for example. In this manner, in the light-emitting device 100, the current can be injected into the light-emitting layer 30 with good uniformity. Thus, light can be generated with good uniformity at the light-emitting layer 30.

In addition, the difference between the band gap of the material of the light-emitting layer 30 and the band gap of the semiconductor layer 60 may be greater than the difference between the band gap of the semiconductor layer 60 and the band gap of the material of the GaN-based semiconductor layer 40. In this manner, the energy barrier of the semiconductor layer 60 and the GaN-based semiconductor layer 40 can be reduced, and the contact resistance of the semiconductor layer 60 and the GaN-based semiconductor layer 40 can be reduced.

In the light-emitting device 100, the semiconductor layer 60 of the second conductivity type is composed of 4H-SiC, and the GaN-based semiconductor layer 40 is a GaN layer. The lattice constant of 4H-SiC is close to the lattice constant of GaN. Therefore, in the light-emitting device 100, the semiconductor layer 60 is easily lattice-matched to the GaN-based semiconductor layer 40, with less crystal defects. In this manner, the absorption loss of the light generated at the light-emitting layer 30 due to the semiconductor layer 60 can be reduced.

In the light-emitting device 100, the second multi layer film mirror 70 is composed of the plurality of dielectric layers 72. Thus, in the light-emitting device 100, the refractive index difference of the high refractive index layer and the low refractive index layer making up the DBR can be larger and the reflection band can be wider in comparison with the case where the second multi layer mirror film is composed of a plurality of GaN-based semiconductor layers, for example.

In the light-emitting device 100, the first conductivity type is the n-type, and the second conductivity type is the p-type. The p-type GaN-based semiconductor layer 40 has higher resistivity than an n-type GaN-based semiconductor layer, but since the semiconductor layer 60 is provided with the light-emitting device 100, the current can be injected into the light-emitting layer 30 with good uniformity.

### 2. Manufacturing Method of Light-Emitting Device

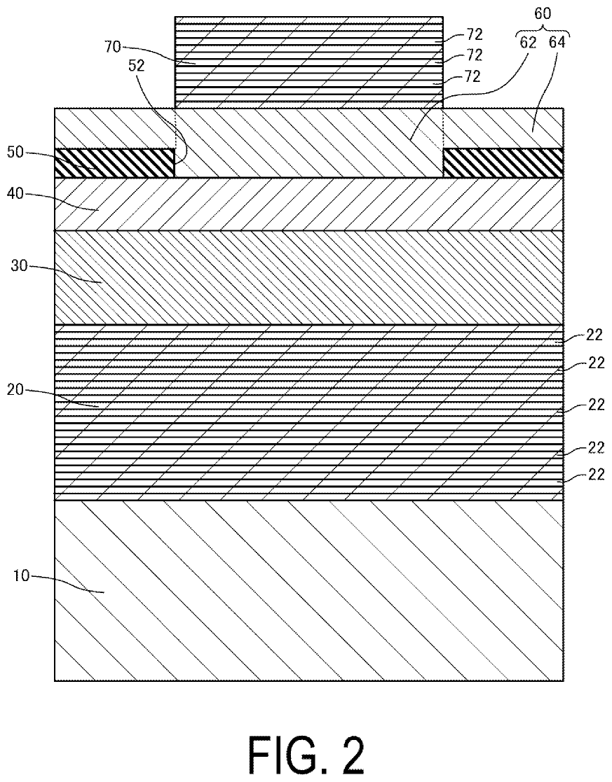

Next, a manufacturing method of the light-emitting device 100 according to the embodiment is described with reference to the drawings. FIG. 2 is a sectional view schematically illustrating a manufacturing process of the light-emitting device 100 according to the embodiment.

As illustrated in FIG. 2, the plurality of semiconductor layers 22 is formed on the substrate 10 to form the first multi layer film mirror 20. The semiconductor layer 22 is formed by epitaxial growth such as a MOCVD (Metal Organic Chemical Vapor Deposition) method and a MBE (Molecular Beam Epitaxy) method, for example.

Next, the light-emitting layer 30 is formed on the first multi layer film mirror 20. The light-emitting layer 30 is formed by epitaxial growth such as a MOCVD method and a MBE method, for example.

Next, the GaN-based semiconductor layer 40 is formed on the light-emitting layer 30. The GaN-based semiconductor layer 40 is formed by epitaxial growth such as a MOCVD method and a MBE method, for example.

Next, the insulating layer 50 is formed on the light-emitting layer 30. The insulating layer 50 is formed by a CVD (Chemical Vapor Deposition) method, a sputtering method and the like, for example.

Next, patterning is performed on the insulating layer 50 to form the opening 52. The patterning is performed by photolithography and etching, for example.

Next, the semiconductor layer 60 is formed on the GaN-based semiconductor layer 40 and the insulating layer 50. The semiconductor layer 60 is formed by epitaxial growth such as a MOCVD method and a MBE method, for example. Through lateral growth from the opening 52, the semiconductor layer 60 can be epitaxial-grown also on the insulating layer 50. By adjusting the growth temperature, the semiconductor layer 60 with a high 4H-SiC content, preferably the semiconductor layer 60 composed of 4H-SiC, can be formed.

Note that the semiconductor layer 60 may be formed by a sputtering method, a vacuum deposition method or the like, not by epitaxial growth, for example. It should be noted that in consideration of reduction of crystal defects, it is preferable to form the semiconductor layer 60 by epitaxial growth.

Next, the plurality of dielectric layers 72 is formed on the semiconductor layer 60 to form the second multi layer film mirror 70. The dielectric layer 72 is formed by a CVD method, a sputtering method or the like, for example.

As illustrated in FIG. 1, the first electrode 80 is formed below the substrate 10. Next, the second electrode 82 is formed on the semiconductor layer 60. The first electrode 80 and the second electrode 82 are formed by a vacuum deposition method and a sputtering method, for example. Note that the order of the formation of the first electrode 80 and the second electrode 82 is not limited.

Through the above-described processes, the light-emitting device 100 can be manufactured.

### 3. Modifications of Light-Emitting Device

### 3.1. First Modification

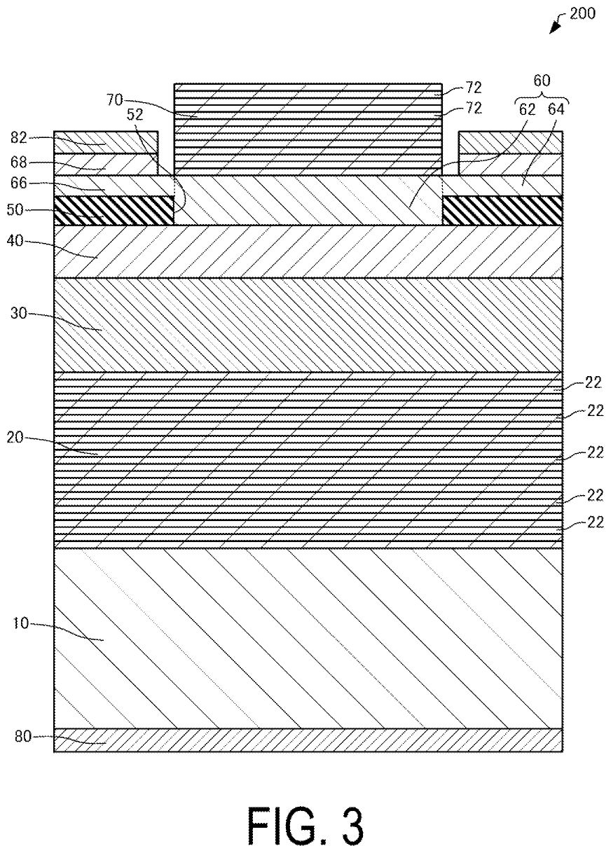

Next, a light-emitting device according to the first modification of the embodiment is described with reference to the drawings. FIG. 3 is a sectional view schematically illustrating a light-emitting device 200 according to the first modification of the embodiment. In the following description, in the light-emitting device 200 according to the first modification of the embodiment, members with the same functions as those of the components of the above-described light-emitting device 100 according to the embodiment are denoted with the same reference numerals, and the description thereof is omitted.

The light-emitting device 200 is different from the above-described light-emitting device 100 in that the semiconductor layer 60 includes a first layer 66 and a second layer 68 as illustrated in FIG. 3.

The first layer 66 is provided on the GaN-based semiconductor layer 40 and the insulating layer 50. The first layer 66 is provided between the GaN-based semiconductor layer 40 and the second multi layer film mirror 70, and between the insulating layer 50 and the second layer 68. The first portion 62 of the semiconductor layer 60 is composed of the first layer 66.

The second layer 68 is provided on the first layer 66. The second layer 68 is provided between the first layer 66 and the second electrode 82. The second portion 64 of the semiconductor layer 60 is composed of the first layer 66 and the second layer 68. The second layer 68 surrounds the second multi layer film mirror 70 as viewed in the lamination direction, for example.

The impurity concentration of the second layer 68 is higher than the impurity concentration of the first layer 66. The fact that the impurity concentration of the second layer 68 is higher than the impurity concentration of the first layer 66 can be confirmed by an atom probe analysis method, for example.

In the light-emitting device 200, the semiconductor layer 60 includes the first layer 66 and the second layer 68 with an impurity concentration higher than that of the first layer 66, and the second layer 68 is provided between the first layer 66 and the second electrode 82. Thus, in the light-emitting device 200, the second layer 68 with the higher impurity concentration can reduce the contact resistance of the semiconductor layer 60 and the second electrode 82. Further, the first layer 66 with the low impurity concentration can reduce absorption loss of the light generated at the light-emitting layer 30 due to the semiconductor layer 60.

### 3.2. Second Modification

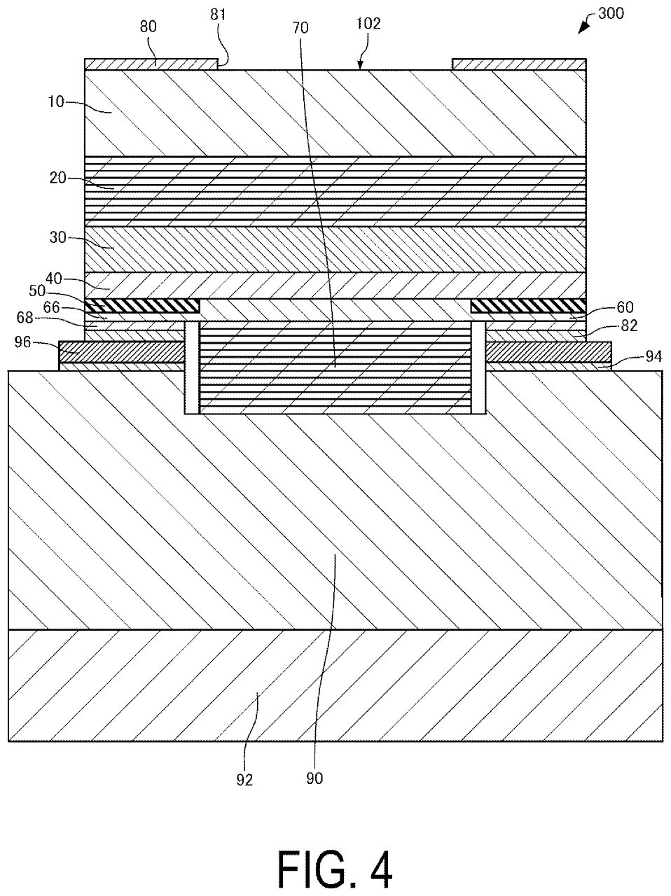

Next, a light-emitting device according to a second modification of the embodiment is described with reference to the drawings. FIG. 4 is a sectional view schematically illustrating a light-emitting device 300 according to the second modification of the embodiment. In the following description, in the light-emitting device 300 according to the second modification of the embodiment, members with the same functions as those of the components of the above-described light-emitting device 100 according to the embodiment and the light-emitting device 200 according to the first modification of the embodiment are denoted with the same reference numerals, and the description thereof is omitted.

As illustrated in FIG. 4, the light-emitting device 300 is different from the above-described light-emitting device 100 in that a submount 90 is provided. In the example illustrated in the drawing, the semiconductor layer 60 of the light-emitting device 300 includes the first layer 66 and the second layer 68 as with the above-described semiconductor layer 60 of the light-emitting device 200.

The submount 90 is provided at a supporting substrate 92. The material of the submount 90 is SiC, for example. The supporting substrate 92 is an Si substrate, for example. The submount 90 is provided with a terminal 94. The terminal 94 is provided on the side opposite to the supporting substrate 92 of the submount 90. The material of the terminal 94 is metal, for example.

The substrate 10, the first multi layer film mirror 20, the light-emitting layer 30, the GaN-based semiconductor layer 40, the insulating layer 50, the semiconductor layer 60, the second multi layer film mirror 70, and the electrodes 80 and 82 make up a light-emitting element 102. The light-emitting element 102 is junction-down mounted at the submount 90. The second multi layer film mirror 70 is provided between the submount 90 and the semiconductor layer 60.

An opening 81 is formed in the first electrode 80. The light-emitting device 300 emits laser light from the opening 81. The second electrode 82 is coupled to the terminal 94 through bonding member 96. The bonding member 96 is a solder or a silver paste, for example.

The light-emitting device 300 includes the substrate 10 and the submount 90, the first multi layer film mirror 20 is provided between the substrate 10 and the light-emitting layer 30, and the second multi layer film mirror 70 is provided between the submount 90 and the semiconductor layer 60. In this manner, the light-emitting device 300 can dissipate the heat generated at the light-emitting layer 30, through the submount 90.

### 4. Three-Dimensional Shaping Apparatus

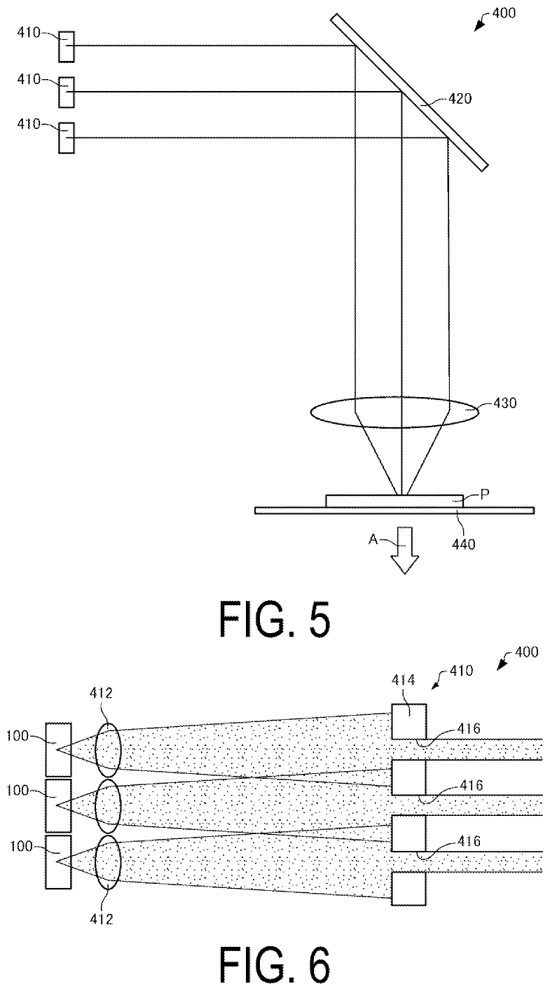

Next, a three-dimensional shaping apparatus according to the embodiment is described with reference to the drawings. FIG. 5 is a diagram schematically illustrating a three-dimensional shaping apparatus 400 according to the embodiment.

As illustrated in FIG. 5, the three-dimensional shaping apparatus 400 includes a light source 410, a galvano scanner 420, a lens 430, and a stage 440, for example. The three-dimensional shaping apparatus 400 is a powder-head 3D printer.

A plurality of the light sources 410 is provided. The plurality of light sources 410 is disposed side by side in a predetermined direction. The plurality of light sources 410 emits laser light. Here, FIG. 6 is a diagram schematically illustrating the light source 410.

As illustrated in FIG. 6, the light source 410 includes the light-emitting device 100, a lens 412, and a slit plate 414, for example. A plurality of the light-emitting devices 100 is provided. The plurality of light-emitting devices 100 is disposed side by side in a predetermined direction. A plurality of the lenses 412 is provided in a manner corresponding to the light-emitting device 100. The lens 412 focuses light emitted from the light-emitting device 100. In the slit plate 414, a plurality of slits 416 is formed in a manner corresponding to the light-emitting device 100. The slit 416 extracts more parallel components from the light emitted from the lens 412. Note that although not shown in the drawings, the light source 410 may include a uniform illumination system that increases the uniformity of the intensity of light emitted from the plurality of light-emitting devices 100.

As illustrated in FIG. 5, the galvano scanner 420 reflects light emitted from the light source 410. The light reflected by the galvano scanner 420 is applied to a metal powder P of the stage 440 through the lens 430. The galvano scanner 420 can control the travelling direction of light. In this manner, the light reflected by the galvano scanner 420 can be exactly applied to the metal powder P.

The lens 430 focuses light reflected by the galvano scanner 420. The light emitted from the lens 430 is applied to the metal powder P. The part of the metal powder P irradiated with the light is sintered.

The stage 440 supports the metal powder P. After the metal powder P is irradiated and sintered with light, the stage 440 moves in the direction away from the lens 430 as indicated by the arrow A. Then, additional metal powder is supplied on the sintered metal powder P, and light emitted from the light source 410 is applied to the additional metal powder. By repeating predetermined times the movement of the stage 440, the supply of metal powder, and the light irradiation of the metal powder, a three-dimensional object with a predetermined shape is shaped.

### 5. Modifications of Three-Dimensional Shaping Apparatus

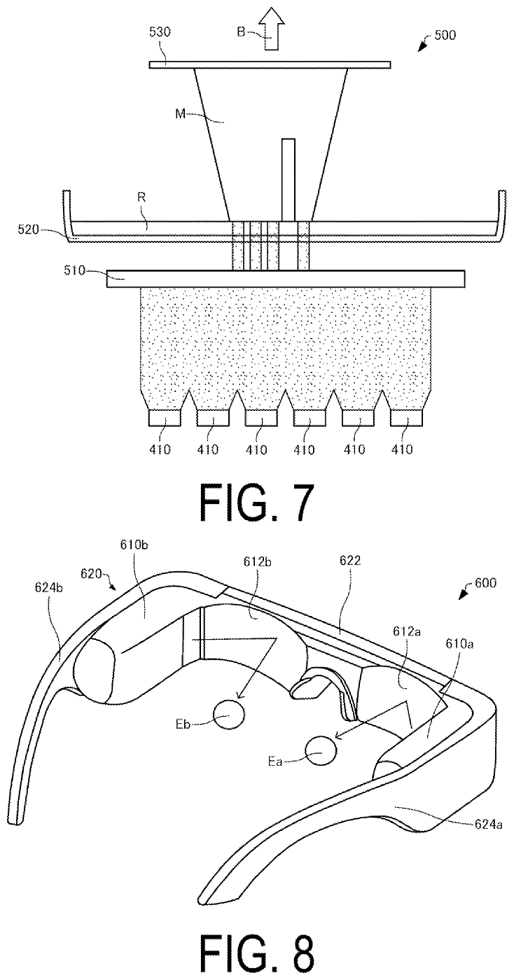

Next, a three-dimensional shaping apparatus according to a modification of the embodiment is described with reference to the drawings. FIG. 7 is a diagram schematically illustrating a three-dimensional shaping apparatus 500 according to a modification of the embodiment. In the following description, in the three-dimensional shaping apparatus 500 according to the modification of the embodiment, members with the same functions as those of the components of the above-described three-dimensional shaping apparatus 400 according to the embodiment are denoted with the same reference numerals, and the description thereof is omitted.

The above-described three-dimensional shaping apparatus 400 is a powder-head 3D printer as illustrated in FIG. 5.

On the other hand, the three-dimensional shaping apparatus 500 is a stereo lithography 3D printer using an ultraviolet curable resin as illustrated in FIG. 7.

The three-dimensional shaping apparatus 500 includes the light source 410, a DLP (Digital Light Processing) 510, a container 520, and a stage 530, for example.

Light emitted from the plurality of light sources 410 enters the DLP 510. In response to the light emitted from the plurality of light sources 410, the DLP 510 emits light from a predetermined pixel. The light emitted from the DLP 510 is applied to a resin material R in the container 520. The resin material R is an ultraviolet curable resin. The part of the resin material R irradiated with the light is cured.

The cured portion of the resin material R adheres to the stage 530. After the cured portion is adhered to the stage 530, the stage 530 moves in the direction away from the container 520 as indicated by an arrow B. By repeating the irradiation of the resin material R with light and the movement of the stage 530 predetermined times, a three-dimensional object M with a predetermined shape is shaped.

Note that the resin material R may include ceramic. In this manner, the three-dimensional object M composed of ceramic can be shaped. In addition, instead of the DLP 510, an LCD (Liquid Crystal Display) may be used.

### 6. Head-Mounted Display

Next, a head-mounted display (HMD) according to the embodiment is described with reference to the drawings. FIG. 8 is a perspective view schematically illustrating an HMD 600 according to the embodiment.

As illustrated in FIG. 8, the HMD 600 is a head-mounted type image display device. The HMD 600 includes a right-eye image light generation unit 610a, a right ophthalmic deflection member 612a that deflects image light emitted from the right-eye image light generation unit 610a such that the light enters the right eye Ea of the viewer, a left-eye image light generation unit 610b, and a left ophthalmic deflection member 612b that deflects image light emitted from the left-eye image light generation unit 610b such that the light enters the left eye Eb of the viewer, for example.

The HMD 600 has an eyeglasses-like shape, for example. The HMD 600 includes a frame 620. The frame 620 is mounted on the viewer's head. The frame 620 includes a front portion 622, a right temple 624a, and a left temple 624b, for example. The front portion 622 supports the right ophthalmic deflection member 612a and the left ophthalmic deflection member 612b. The right temple 624a supports the right-eye image light generation unit 610a. The left temple 624b supports the left-eye image light generation unit 610b.

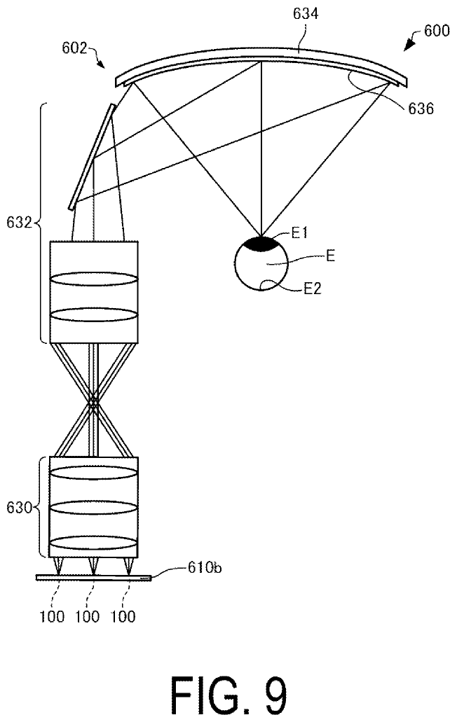

FIG. 9 is a diagram for describing an optical system of the HMD 600. Basically, the right-eye image light generation unit 610a and the left-eye image light generation unit 610b have the same configuration. Therefore, only the configuration of the left-eye image light generation unit 610b is described below, and the description of the right-eye image light generation unit 610a is omitted.

As illustrated in FIG. 9, the HMD 600 includes a projection-based optical unit 630, a correction-based optical unit 632, and a diffraction element 634. Along the travelling direction of the image light emitted from the left-eye image light generation unit 610b, the projection-based optical unit 630, the correction-based optical unit 632, and the diffraction element 634 are disposed in this order, for example. The projection-based optical unit 630, the correction-based optical unit 632, and the diffraction element 634 make up a light guided apparatus 602 that forms the light path of the image light.

The left-eye image light generation unit 610b generates image light. The left-eye image light generation unit 610b includes the light-emitting device 100, and a liquid crystal display element not illustrated in the drawing, for example. A plurality of the light-emitting devices 100 is provided. In response to the light emitted from the light-emitting device 100, the liquid crystal display element emits image light. Since the light-emitting device 100 emits laser light with a narrow wavelength, the HMD 600 does not require a wavelength compensation element for compensating the wavelength. In this manner, the weight and cost of the HMD 600 can be reduced. The image light generated at the left-eye image light generation unit 610b enters the projection-based optical unit 630.

The projection-based optical unit 630 is composed of an optical element such as a lens and a mirror. The projection-based optical unit 630 has a function of controlling the radiation angle of image light. More specifically, the projection-based optical unit 630 adjusts image light generated by the left-eye image light generation unit 610b, to a parallel light flux with an angle corresponding to the generated position. In this manner, the image light generated by the left-eye image light generation unit 610b can be efficiently guided to the correction-based optical unit 632.

The correction-based optical unit 632 is composed of an optical element such as a lens and a mirror, for example. The correction-based optical unit 632 has a function of correcting aberration such as distortion of image light. In this manner, the image light after the correction of aberration can be efficiently guided to the diffraction element 634.

The diffraction element 634 is provided at the left ophthalmic deflection member 612b. The diffraction element 634 is composed of a reflective volume holographic element, for example. The reflective volume holographic element is a partially reflective diffractive optical element, and the left ophthalmic deflection member 612b is a partially transmissive and reflective combiner. In this manner, external light also enters the eye E through the left ophthalmic deflection member 612b. In this manner, the viewer can visually recognize a combined image of the image light formed by the left-eye image light generation unit 610b and the external light.

An incidence surface 636 of the diffraction element 634 is a concave surface that faces the viewer and is recessed in the direction away from the eye E. In other words, the incidence surface 636 has a shape of which the center portion is curved in a concave manner with respect to the periphery in the incidence direction of the image light. In this manner, the image light can be efficiently focused toward the eye E of the viewer. Then, the viewer recognizes the image when the image light reaches the retina E2 through the pupil hole E1 of the eye E.

The above-described light-emitting device according to the embodiment can be used for applications other than three-dimensional shaping apparatuses and HMDs. The above-described light-emitting device according to the embodiment is used for the light source of projectors, indoor and outdoor illuminators, laser printers, scanners, in-vehicle lights, sensing apparatuses such as pulse measuring devices using light, and communication devices, for example.

The above-described embodiments and modifications are merely examples, and they are not limitative. For example, the embodiments and modifications may be combined as necessary.

The present disclosure includes configurations that are substantially identical to the configurations described in the embodiments, e.g., configurations that are identical in function, method, and result, or identical in purpose and effect. The present disclosure also includes configurations in which non-essential parts of the configurations described in the embodiments are replaced. The present disclosure also includes configurations that have the same action effect or can achieve the same purpose as the configurations described in the embodiments. The present disclosure also includes a configuration in which a known technology is added to the configuration described in the embodiments.

The following contents can be derived from the embodiments and modifications described above.

A light-emitting device according to one aspect includes a first multi layer film mirror composed of a plurality of first semiconductor layers each having first conductivity type, a second multi layer film mirror, a light-emitting layer provided between the first multi layer film mirror and the second multi layer film mirror, a GaN-based semiconductor layer having second conductivity type different from the first conductivity type, the GaN-based semiconductor layer being provided between the light-emitting layer and the second multi layer film mirror, a second semiconductor layer having the second conductivity type, the second semiconductor layer including a first portion provided between the GaN-based semiconductor layer and the second multi layer film mirror, and a second portion not overlapping the second multi layer film mirror as viewed in a lamination direction of the first multi layer film mirror and the light-emitting layer, and an electrode provided at the second portion. A band gap of a material of the second semiconductor layer is greater than a band gap of a material of the light-emitting layer, and smaller than a band gap of a material of the GaN-based semiconductor layer.

With this light-emitting device, the current can be injected with good uniformity to the light-emitting layer.

In the light-emitting device according one aspect, the second semiconductor layer may be composed of 4H-SiC, and the GaN-based semiconductor layer may be a GaN layer.

With this light-emitting device, the absorption loss of the light generated at the light-emitting layer due to the SiC layer can be reduced.

In the light-emitting device according one aspect, the second semiconductor layer may include a first layer, and a second layer with an impurity concentration higher than that of the first layer, and the second layer may be provided between the first layer and the electrode.

With this light-emitting device, the second layer with a high impurity concentration can reduce the contact resistance of the semiconductor layer of the second conductivity type and the electrode. Further, the first layer with a low impurity concentration can reduce the absorption loss of the light generated at the light-emitting layer due to the semiconductor layer of the second conductivity type.

The light-emitting device according one aspect may further include a substrate, and a submount. The first multi layer film mirror may be provided between the substrate and the light-emitting layer, and the second multi layer film mirror may be provided between the submount and the semiconductor layer of the second conductivity type.

With this light-emitting device, the heat generated at the light-emitting layer can be dissipated through the submount.

In the light-emitting device according one aspect, the second multi layer film mirror may be composed of a plurality of dielectric layers.

With the light-emitting device, the refractive index difference of the high refractive index layer and the low refractive index layer making up the DBR can be increased, and the reflection band can be broadened.

In the light-emitting device according one aspect, the first conductivity type may be an n-type, and the second conductivity type may be a p-type.

With this light-emitting device, while the resistivity of the p-type GaN-based semiconductor layer is higher than that of the n-type GaN-based semiconductor layer, the current can be injected with good uniformity to the light-emitting layer because the SiC layer is provided.

A three-dimensional shaping apparatus according to one aspect includes the light-emitting device.

A head-mounted display according to one aspect includes the light-emitting device.

What is claimed is:

1. A light-emitting device, comprising:
a first multi layer film mirror composed of a plurality of first semiconductor layers each having a first conductivity type;
a second multi layer film mirror;
a light-emitting layer provided between the first multi layer film mirror and the second multi layer film mirror;
a GaN-based semiconductor layer having a second conductivity type different from the first conductivity type, the GaN-based semiconductor layer being provided between the light-emitting layer and the second multi layer film mirror;
a second semiconductor layer having the second conductivity type, the second semiconductor layer including a first portion provided between the GaN-based semiconductor layer and the second multi layer film mirror, and a second portion not overlapping the second multi layer film mirror as viewed in a lamination direction of the first multi layer film mirror and the light-emitting layer; and
an electrode provided at the second portion, wherein
a band gap of a material of the second semiconductor layer is greater than a band gap of a material of the light-emitting layer, and smaller than a band gap of a material of the GaN-based semiconductor layer.

2. The light-emitting device according to claim 1, wherein
the second semiconductor layer is composed of 4H-SiC, and
the GaN-based semiconductor layer is a GaN layer.

3. The light-emitting device according to claim 1, wherein
the second semiconductor layer includes:
a first layer, and
a second layer with an impurity concentration higher than that of the first layer, and
the second layer is provided between the first layer and the electrode.

4. The light-emitting device according to claim 1, further comprising:
a substrate; and
a submount, wherein
the first multi layer film mirror is provided between the substrate and the light-emitting layer, and
the second multi layer film mirror is provided between the submount and the semiconductor layer of the second conductivity type.

5. The light-emitting device according to claim 1, wherein the second multi layer film mirror is composed of a plurality of dielectric layers.

6. The light-emitting device according to claim 1, wherein
the first conductivity type is an n-type, and
the second conductivity type is a p-type.

7. A three-dimensional shaping apparatus comprising the light-emitting device according to claim 1.

8. A head-mounted display comprising the light-emitting device according to claim 1.
